(19) United States
(12) Patent Application Publication
(10) Pub. No.: US 2016/0118220 A1
(43) Pub. Date: Apr. 28, 2016

(54) GEOMETRIC FIELD ENHANCEMENT TO MAINTAIN ELECTRODE CONDUCTIVITY

(71) Applicant: E/G ELECTRO-GRAPH, INC.

(72) Inventor: MICHAEL VELLA, SAN LEANDRO, CA (US)

(73) Assignee: E/G ELECTRO-GRAPH, INC., VISTA, CA (US)

(21) Appl. No.: 14/921,691

(22) Filed: Oct. 23, 2015

Related U.S. Application Data
(60) Provisional application No. 62/067,693, filed on Oct. 23, 2014.

(51) Int. Cl. H01J 37/30; H01L 21/02

(52) U.S. Cl. CPC H01J 37/30; H01L 21/02041

(57) ABSTRACT

Features that create localized electric field enhancement are deliberately introduced on conductors where deposits having insulating characteristics can form. The purpose of the introduced features is to enhance localized breakdown of the deposits in order to maintain electrode conductivity.

### CROSS-REFERENCE TO RELATED APPLICATIONS

The present application claims benefit of co-pending Provisional Patent Application No. 62/067,693, filed on Oct. 23, 2014; that application being incorporated herein, by reference, in its entirety.

### BACKGROUND OF THE INVENTION

### Field of the Invention

The invention relates to electrical devices where deposits can form on conducting surfaces as part of routine operation, especially deposits that act as insulators and, more particularly, to systems, methods and devices for removing these deposits during normal operation.

In clean, ideal conditions, candidate conductors typically operate below the threshold for electrical breakdown, to allow for the degradation of voltage holding associated with the contamination that is expected in normal operation. Deposits can be a loose, unbound accumulation of material, such as, dust. Deposits can also take the form of an attached layer, or, be formed by chemical reaction. Examples include corona rings, insulator gradient rings, and spark gaps exposed to contamination, such as, spark plugs. Electrodes in vacuum systems, such as, charged particle accelerators and plasma tools, are given special attention. In liquid, gas, or vacuum environments, electrode contaminants can require maintenance, or, lead to high voltage breakdown.

In semiconductor vacuum based manufacturing tools, such as, plasmas and ion beams, breakdowns caused by the formation of deposits can increase particle generation. On powered electrodes, hard power supply breakdowns (also called ‘glitches’), cause significantly increased particle generation. This is undesirable as particles cause yield loss in semiconductor manufacturing, and are especially troublesome as features size decreases, because the particle population scales inversely with particle size. Therefore, semiconductor tool qualification and continued operation requires maintaining minimum particle counts, which are routinely monitored.

### Electrode and Insulator Technology

Engineering practice in high voltage systems has evolved since the 1800's. The electric field at the surface of a conductor scales inversely with the radius of curvature. So, routine practice has become to minimize geometric electric field enhancement by using smooth, clean surfaces with large radius of curvature. Maximum voltage holding and breakdown are typically characterized under carefully controlled, clean, ‘ideal’ conditions. Then, degradation can be studied by adding contaminants. The effect of contamination on electrode voltage holding has been routinely studied for power systems that operate in atmospheric conditions, but little has been published for semiconductor manufacturing. In a vacuum, electrode deposits have been shown to reduce the breakdown voltage to a fraction of that for clean electrodes. See, for example, Vanderberg, et. al., “Evaluation of electrode materials for ion implanters”, IEEE 0-7803-X/99, p207-210.

Some systems, such as, electron microscopes, operate near the threshold for hard breakdown, and the bias potential must be shut off. A system like this, near ideal threshold, cannot tolerate field enhancement. However, many systems function far from ideal conditions, such as, commercial power systems exposed to atmospheric conditions. Experienced practice makes allowance for contamination by operating at reduced electrical field. Similarly, in a high current density, DC ion accelerator with clean electrodes in clean vacuum, design field can be nominally 100 kV/cm. In an industrial accelerator where contaminants can accumulate, design field may be reduced to 30 kV/cm or less, in anticipation of electrode contamination.

An ideal insulator draws net zero current, neglecting leakage. If normal functionality of a device relies on net current from a conducting surface, the presence of an insulator can compromise system performance by reducing current. Insulating deposits can also cause breakdowns. In an environment with free charge, most of the potential drop appears across the insulator, because it is a poor conductor. In practice, no insulator is perfect, and even deposits with leakage, like boron or silicon, can cause breakdowns and particle generation.

Accumulated charge on an insulator surface can be released by breakdown of the insulator itself, or, by unipolar surface arc. For example, lightening is a natural phenomena where charge accumulates in a cloud and creates a potential difference that breaks down the air 10, which serves as insulator between the cloud 20 and ground 30, as illustrated in FIG. 1. By contrast, unipolar arcs release stored charge by surface micro explosions. See, for example, Kajita et al., “Tungsten erosion by the initiation of unipolar arcs in nuclear fusion devices”, 30th ICPIG, Belfast, UK, 2011; Robson, et al., “An arc maintained on an isolated metal plate exposed to a plasma”, Proc. Phys. Soc. 73, 508, 1959. Unipolar arcs release gas and particle bursts. Once the stored charge is dissipated, these breakdowns end.

For powered electrodes, breakdowns may end spontaneously, but some require power supply intervention. Transient, low current electrical activity is always present around high voltage systems. In air or vacuum, this is often called corona. Corona cleaning, or, plasma discharge cleaning, is well known, and has often been used as a conditioning process for high voltage electrodes. Transient activity can be monitored by tracking current or voltage, but the definition of ‘breakdown’ is subjective, depending on systems requirements. In general, breakdown protection thresholds are set to react fast enough to minimize system damage.

Many electrodes are not powered, but still play a functional role. For example, in a positive ion beam system, parts of the beamline that are at local ground potential effectively function as cold cathodes relative to the beam. Grounded electrodes may supply low level electron current that is important to beam stability or divergence.

Semiconductor plasma and beam systems can be dc, rf, and/or pulse powered. They are used for etching, cleaning, doping, and material deposition. Semiconductor processes can include particularly harsh operating conditions, such as, simultaneous refractory temperatures, oxidizing chemicals, and energetic particle bombardment. Electrodes can accumulate deposits as process by-products. Insulating deposits can be particularly troublesome, especially in the presence of free charge or ionizing radiation. On the other hand, a class of industrial products, Siemens dielectric barrier discharges, found a way to make productive use of the properties of insulators on electrodes. See, for example, Kogelschatz et al., “Dielectric-Barrier Discharges. Principle and Applications”, Journal de Physique IV, 1997, 07 (C4), pp. C4-47-C4-66.

Ion beam systems are especially complex, most are dc but some are rf. They can combine high voltage, magnetic and/or electrical charged particle analysis, and target scanning. Insulating layers can form on various apertures, liners, beam stops and optics, especially near the process surface.

### Description of the Related Art

Until colonial times, lightning strikes frequently caused building fires. The famous solution proposed by Benjamin Franklin in 1749 was the lightning rod 40, essentially a grounded iron rod with a sharp tip, as illustrated in FIG. 2.

The electric field at the tip of the Franklin rod 40 was known to actually have caused more lightning strikes than would otherwise occur. In 1918, to reduce the rate of lightning strikes, Tesla patented the lightning protector 50 of FIG. 3, which features a gently curved conductor 55 to reduce the electric field. This kind of geometric field reduction became routine in high voltage systems.

Patterning, roughing, or texturing of the surface area has been used to increase the available surface for accumulation of deposits, to improve the adhesion of deposits, and to reduce the size of flakes that do break off. Patterning has also been used to reduce beam energy contamination. See, for example, U.S. Pat. Nos. 4,560,879 to Wu et al.; 6,576,909 to Donaldson et al.; 7,807,984 to Alcott et al.; 7,838,849 to Alcott et al.; 8,963,107 to Eisner et al.; and U.S. Patent Application Publication Nos. 2007/0102652 to Ring et al.; and 2008/0164427 to Collart et al. Patterning has not been used specifically to introduce corona activity.

In vacuum, gas, or non-conducting liquid systems, the confluence of medium-metal-insulator is called a “triple junction” (or “triple point”). Electric field enhancement in the insulators at triple junctions has been recognized as a cause of insulator breakdown. See, for example, Chung et al., “Configuration-dependent enhancements of electric fields near the quadruple and the triple junction”, J. Vac. Sci. Tech. B28, C2A94, 2010; .Stygar et al., “Improved design of a high-voltage vacuum-insulator interface”, Phys. Rev. ST Accel Beams 8, 050401 (2005). Depending on geometry, triple junction insulator field enhancement can trigger anode or cathode breakdowns. The goal of most research and development has been to increase insulator service life by minimizing field stress and breakdowns at triple junctions. See, for example, U.S. Patent Application Publication No. 2014/0184055. However, triple junction field enhancement has also been productively used in dielectric barrier discharges. See, for example PCT Application Publication No. WO 2004/026461 A1.

What is needed is a system, device and method for producing a localized field that enhances corona cleaning on a conductor.

### BRIEF SUMMARY OF THE INVENTION

It is accordingly an object of the invention to add localized field enhancement features to conductors to enhance corona activity and effectuate plasma cleaning activity (and/or localized breakdowns) around the field enhanced features to keep some electrode area relatively clean, and thereby maintain functionality. For applications, such as semiconductor manufacturing, where particle generation is an issue, another intended benefit is expected to be reduction of net particle generation over the service life. In one particular embodiment of the invention, local field enhancement is produced by at least one of geometric electric field enhancement, surface roughness, triple junctions, or, a combination of these.

Although the invention is illustrated and described herein as embodied in geometric field enhancement to maintain electrode conductivity, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a schematic illustration of charge accumulated in a cloud, air insulation, and ground;

FIG. 2 is a simplified Illustration of Benjamin Franklin's lightning rod in use;

FIG. 3 is a simplified Illustration of Tesla's lightning protector as provided in U.S. Pat. No. 1,266,175;

FIGS. 4 and 5 illustrate possible locations for field enhanced rods or fins in a generic RF powered parallel plate plasma chamber, in accordance with particular embodiments of the present invention;

FIG. 6 is an illustration of an array of field enhanced fins oriented parallel to an ion beam in accordance with another particular embodiment of the present invention;

FIG. 7 shows simulated electrostatic potential contours are plotted for a 1 cm gap with 10 kV potential difference to illustrate that closely spaced features can provide localized field enhancement without generating large scale fields in the gap;

FIG. 8 is an illustration of insulating deposits on a field enhanced feature. Ideally, corona activity near the tip will keep the tip relatively clean;

FIG. 9A is an illustration of a two piece electrode assembly, in which a relative bias (in this case positive) is applied to the field enhanced feature; and

FIG. 9B is an illustration of the two piece electrode assembly of FIG. 9A, additionally showing the deposits formed.

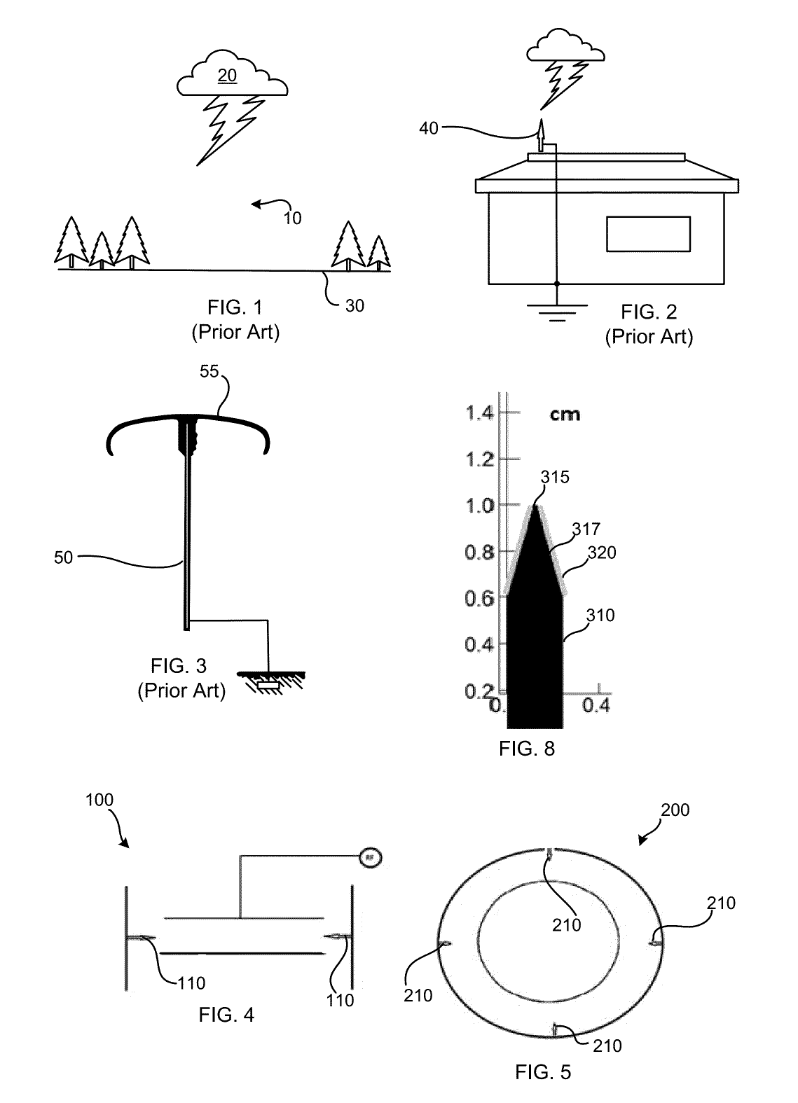

### DETAILED DESCRIPTION OF THE INVENTION

One goal of the present invention is to provide a system having localized field enhancement features (i.e., defined herein as geometric features, formations or structures) that are added to conductors in order to enhance localized corona activity at the conductors. Such localized corona activity results in the occurrence of localized breakdowns that keep some electrode area relatively clean, and thereby maintain electrode functionality. In effect, the present invention is used to induce localized plasma cleaning activity around the added field enhanced features. For practical applications, such as semiconductor manufacturing, where particle generation is a concern, another intended benefit would be the reduction of net particle generation over the service life of the conductor. Local field enhancement can be produced by geometric electric field enhancement features, surface roughness, triple junctions, or, a combination of these, among other things.

Many practical aspects of electrostatics depend on the actual physical parameters. For example, mega volt technology differs significantly 1 Volt technology. The breakdown voltage of a given insulating material depends on the actual thickness. A 1 micron thick sample differs significantly in real properties from a 1 cm thick, or, 1 m thick sample. Systems with micron scale features or very high electric fields can have quantum emission effects. However, some aspects of electrostatics scale proportionally, regardless of feature size. For example, the electric field, E, across a pair of parallel plates is simply, E=V/d, where V is the potential difference and d is the distance between the plates. This embeds scale invariance. If V and d change in proportion, then E remains constant, whether the gap is nm, cm, km, etc.

One way to understand geometric field enhancement is to compare the peak electric field of a feature of height h with a plane parallel gap that has the same conductor to conductor distance, d-h. Assuming the features are on the bottom plane, any deviation from the plane creates geometric field enhancement. Although different shaped features create different field, the enhancement of a given shape is scale invariant. For example, consider a single feature for which the ratio of the height to the width (FWHM) is greater than or equal to 1. This will create a field nearly 3× stronger than a planar electrode whether the tip is square or rounded. The enhancement of any shape increases as the relative height increases, i.e., single feature field enhancement increases with height. Arrays are more complicated. Relative height, h, width, w, and spacing, s, affect field enhancement, as illustrated in FIG. 7. Franklin's rod demonstrated that sufficiently high field enhancement will generate electrical breakdown, but the present goal is to use enough enhancement to maintain surface conductivity while minimizing breakdown. Any desired degree of field enhancement can be obtained by adjusting relative dimensions, but the desired degree of enhancement depends on details of the environment and application. For example, in vacuum, free charge, energetic photons, plasma density, chemistry, energetic heavy particles and many other factors affect corona and voltage holding capability, especially for powered electrodes.

Referring now to FIGS. 4 and 5, there are shown two possible embodiments of the invention, wherein field enhanced features 110, 210 have been added (not drawn to scale) into a generic RF plasma tool 100, 200. FIGS. 5A and 5B illustrate only two possible locations for field enhanced features in a generic RF plasma tool. It is not intended that the present invention be limited only to the two embodiments shown in FIGS. 5A and 5B, as other arrangements of geometric features for providing a localized enhanced field may be provided within the scope and spirit of the present invention.

Referring now to FIG. 6, there is shown an array of geometrically field enhanced fins 310 in an ion beam system 300. In this case, the fins 310 are parallel to the direction of the ion beam 320 of FIG. 6. In this case, a combination of modest field enhancement, proximity to beam halo, and ever present divergent beam may be sufficient to keep the tips 315 clean, while deposits accumulate in the troughs. If desired, in order to accommodate ever present beam divergence, it may be desirable to angle some or all of the fins 310 a few degrees relative to the beam direction. If the angle is less than the nominal beam divergence, the rate of halo beam impingement on the tips 315 would be higher near the process surface, to balance the higher rate of backscatter deposition near the process surface. Alternatively, the relative geometric field enhancement could be increased by design near the process surface.

Simulated potential contours for an array of geometrically field enhanced fins 310 in an electrode gap are illustrated in FIG. 7. Since electric fields are proportional to the gradient of the electrostatic potential, the 2D electrostatic simulation of FIG. 7 illustrates that the local field can be enhanced without significantly introducing large scale fields. Note that the geometric field enhancement of an array depends on relative shape, height, width, and spacing of the features, and is controllable by design.

The size of a geometric feature 310, in centimeters, for one particular embodiment is illustrated in FIG. 8. However, the invention is not to be limited only to geometric features having the sizes provided in FIG. 8. Other sizes, larger and smaller, may be used without departing from the scope and spirit of the present invention. In fact, simulations conducted on arrays of geometric features having dimensions in centimeters, millimeters, and meters confirmed that relative feature size produces the same geometric field enhancement, within the accuracy of the simulation mesh. It should be noted that geometric field enhancement has even been used for sub-micron devices (see, for example, U.S. Pat. No. 5,739,628 to Tanaka), and such a use can be made in connection with the present invention, if desired.

One particular goal of the present invention is to create geometric features that cause a beneficial level of corona activity, and which do not lead to massive breakdowns or glitches. The benefits and disadvantages of high geometric field enhancement have been known since the time of Benjamin Franklin (see, for example, FIG. 2). On the other hand, Tesla's solution (FIG. 3) of minimizing electric field may not be optimum for environments where deposits or corrosion degrade electrode function. One goal of the present invention is to optimize field enhancement to increase electrode service life in applications where modest increase in corona activity is tolerable. In the case of semiconductor manufacturing, another goal is to reduce particle generation over a maintenance cycle.

Further, although described herein as fins 310, the shape of the geometric features may be altered without departing from the scope or spirit of the present invention. For example, a series of sharp points, instead of fins 310, would also serve for geometric field enhancement, in accordance with the present invention. Optimally, as illustrated more particularly in FIG. 8, it is desired that the tips 315 of the fins/features 310 remain relatively clean, even though deposits 320 accumulate on the sides 317.

The presence of plasma is expected to enhance insulator breakdown activity, although Debye length effects are complicated. ‘Ideal’ breakdown potentials are measured with clean electrodes, without the presence of free charges, ionizing radiation, or, strong fluctuating electric fields. Plasmas have all of these. For features that are large compared with a Debye length, plasma shielding has the effect of placing the opposite electrode conformal to a surface insulator. For example, in a system with positive plasma potential, a ground electrode functions as cold cathode, plasma with positive potential effectively constitutes an anode that conforms to the shape of the electrode and any insulation that forms on the surface. This places most of the potential difference across the insulator. One aspect of a plasma sheath is strong, rapidly fluctuating electric fields. So, insulation formed on features on a scale of, or smaller than, a Debye length would be subjected to this additional stress.

Field enhanced features must be compatible with product requirements, and with the process environment, including chemistry, temperature and sputtering. The most desirable material qualities would combine thermal and electrical conductivity with hardness. To reduce cost, inserts or coatings may be applied to a compatible substrate. For example, tungsten carbide (WC) edge coatings could be formed on graphite fins 310.

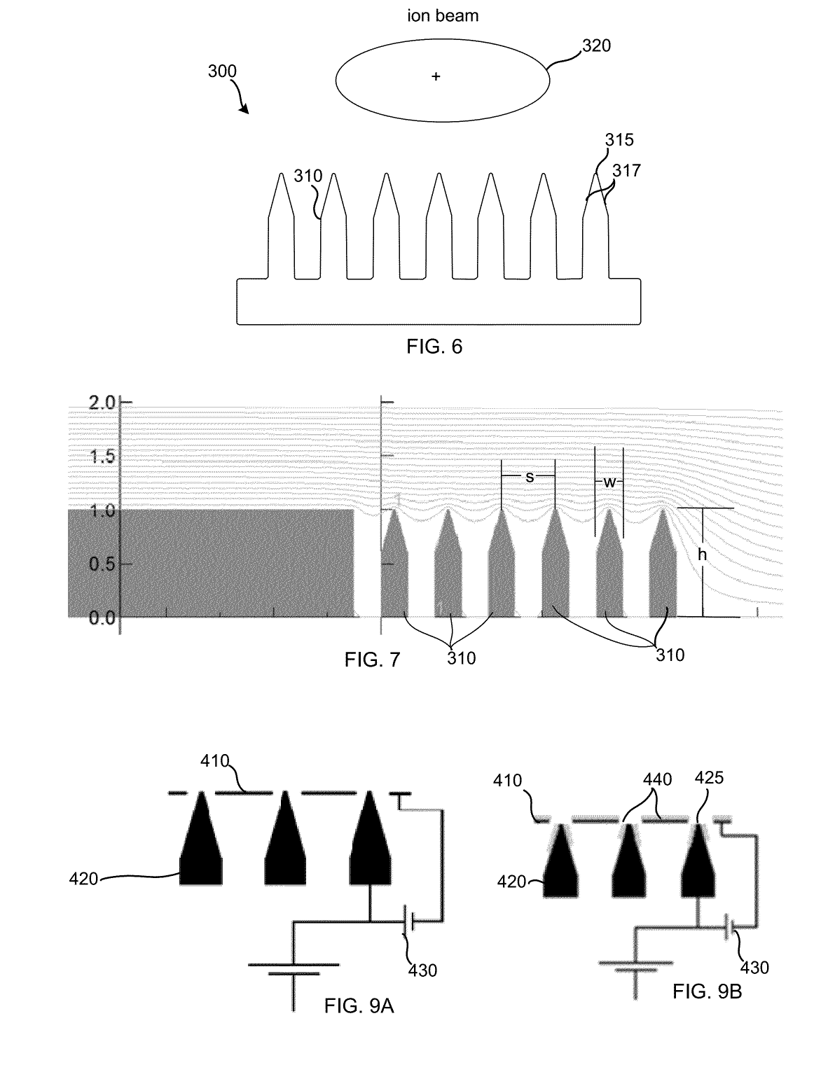

To facilitate the desired effects, pulsed potentials may be applied to specific electrodes. This could be done with existing or with additional power supplies. Alternatively, a two piece electrode configuration 410, 420 could be used with an additional power supply 430, as illustrated in FIG. 9A. Here, the field enhanced features are isolated and biased (in this case positive) relative to the other parts of the electrode to facilitate activity at the preferred sites. This would require a shielded or remote insulator between the pieces. Referring now to FIG. 9B, as with the previously discussed embodiments, the deposits 440 will optimally be deposited only on the electrode 410 and the sides of the features 420, but will not remain on the tip 425 of the features 420, due to the localized enhanced field and resulting localized breakdowns.

Accordingly, the present embodiments of the instant invention relate to, among other things, the deliberate introduction of geometric features that create localized electric field enhancement on conductors where deposits having insulating characteristics can form. The geometric features enhance localized breakdown of the deposits in order to maintain electrode conductivity. In semiconductor manufacturing tools, an expected benefit of the present invention is net particle reduction.

While a preferred embodiment of the present invention is shown and described herein, it will be understood that the invention may be embodied otherwise than as herein specifically illustrated or described, and that within the embodiments certain changes in the detail and construction, as well as the arrangement of the parts, may be made without departing from the principles of the present invention as defined by the appended claims.

I claim:

1. A method for maintaining the conductivity of a conductor in a high voltage system, comprising the steps of:
providing the conductor with at least one geometric feature configured to enhance corona activity around the at least one geometric features; and
operating the system to produce, during normal use, enhanced corona activity around the at least one geometric feature and localized breakdown of deposits formed on the at least one geometric feature.

2. The method of claim 1, wherein insulating deposits form on the sides of the at least one geometric feature, but the tip of the at least one geometric feature is cleaned of deposits by the enhanced corona activity generated around the at least one geometric feature.

3. The method of claim 1, wherein the at least one geometric feature is an array of geometric features configured to enhance corona activity around the geometric features.

4. The method of claim 1, wherein the at least one geometric feature includes at least one fin.

5. The method of claim 4, wherein the at least one geometric feature is an array of fins.

6. The method of claim 1, wherein the at least one geometric feature includes at least one sharp point.

7. The method of claim 6, wherein the at least one geometric feature is a series of sharp points.

8. The method of claim 1, wherein the conductor is an electrode.

9. The method of claim 8, wherein the electrode is an electrically biased electrode.

10. The method of claim 9, wherein the electrode is a two piece electrode and the at least one field enhanced feature is biased relative to the part of the electrode not including the at least one field enhanced feature.

11. The method of claim 1, wherein the ratio of the height to the width (FWHM) of the at least one geometric feature is greater than or equal to 1.

12. A method for performing corona cleaning on a portion of an electrode in a high voltage system, comprising the steps of:
providing the electrode with an array of geometric features configured to enhance corona activity around the geometric features, each geometric feature of the array including a tips; and
operating the system to produce, during normal use, enhanced corona activity around the array of geometric features for corona cleaning deposits from at least the tips of the geometric features of the array.

13. The method of claim 12, wherein each geometric feature is configured as a fin or sharp point having a ratio of the height to the width (FWHM) greater than or equal to 1.

14. The method of claim 12, wherein the electrode is a biased electrode.

15. The method of claim 12, wherein the electrode is a two piece electrode including a first piece including the array and a second piece not including the array, wherein the first piece is electrically biased relative to the second piece.
